(19) United States
(12) Patent Application Publication
(10) Pub. No.: US 2014/0235065 A1
(43) Pub. Date: Aug. 21, 2014

(54) METHOD OF MANUFACTURING SEMICONDUCTOR DEVICE AND SEMICONDUCTOR MANUFACTURING APPARATUS

(71) Applicant: TOKYO ELECTRON LIMITED, Tokyo (JP)

(72) Inventors: Hidetami YAEGASHI, Tokyo (JP); Kenichi OYAMA, Nirasaki City (JP); Masatoshi YAMATO, Nirasaki City (JP)

(73) Assignee: TOKYO ELECTRON LIMITED, Tokyo (JP)

(21) Appl. No.: 14/182,678

(22) Filed: Feb. 18, 2014

(30) Foreign Application Priority Data
Feb. 19, 2013 (JP) 2013-029976

(51) Int. Cl. H01L 21/02

(52) U.S. Cl. CPC H01L 21/02356
USPC 438/758; 355/53

(57) ABSTRACT

Disclosed is a semiconductor device manufacturing method that manufactures a semiconductor device having a resist pattern which is excellent in roughness property and line width property. The method includes forming a film which is elastic and incompatible with a resist patterned on an object to be processed to cover the surface of the resist, and heating the object to be processed formed with the film.

### CROSS-REFERENCE TO RELATED APPLICATIONS

This application is based on and claims priority from Japanese Patent Application No. 2013-029976, filed on Feb. 19, 2013, with the Japan Patent Office, the disclosure of which is incorporated herein in its entirety by reference.

### TECHNICAL FIELD

The present disclosure relates to a semiconductor device manufacturing method and a semiconductor manufacturing apparatus.

### BACKGROUND

In a semiconductor device manufacturing process, when a processing such as, for example, etching, is performed on, for example, a semiconductor wafer (hereinafter, referred to as a “wafer”), a photolithography technology is used. In general, in the photolithography technology, a series of processings are performed in which a resist liquid is coated on a base film of the wafer to form a resist film which is in turn exposed in a desired pattern and then developed. Thereafter, a post-processing, for example, dry etching, is performed by using the resist pattern formed by the photolithography technology as a mask so as to form a desired circuit pattern on the wafer.

A demand for high integration and miniaturization of a semiconductor device has recently been increased, and thus the control of a line width (CD: Critical Dimension) for lines that constitute a circuit on a wafer surface has become important, and miniaturization for the formation of a resist pattern is also required.

In a miniaturization technology of the resist pattern, it is required to control the line width of the resist pattern and to improve parameters such as, for example, a line edge roughness (LER) representing the degree of unevenness on a side wall of a resist line pattern, a line width roughness (LWR) representing the degree of variation of a line width, and a contact edge roughness (CER) representing the degree of unevenness on a side wall of a resist hole pattern. See, e.g., Japanese Patent Laid-Open Publication No. 2012-27144 and Japanese Patent Laid-Open Publication No. 2004-235468.

### SUMMARY

The present disclosure provides a method of manufacturing a semiconductor device. The method includes: forming a film that is elastic and incompatible with a resist to cover a surface of the resist patterned on an object to be processed, and heating the object to be processed that is formed with the film.

The foregoing summary is illustrative only and is not intended to be in any way limiting. In addition to the illustrative aspects, exemplary embodiments, and features described above, further aspects, embodiments, and features will become apparent by reference to the drawings and the following detailed description.

### BRIEF DESCRIPTION OF THE DRAWINGS

FIG. 1 is a flow chart illustrating an example of a semiconductor device manufacturing method according to an exemplary embodiment.

FIGS. 2A to 2D are schematic views for describing a flow of the semiconductor device manufacturing method according to the exemplary embodiment illustrated in FIG. 1.

FIGS. 3A and 3B are schematic views illustrating an example of a heating process in the semiconductor device manufacturing method according to the exemplary embodiment illustrated in FIG. 1.

FIG. 4 is a schematic plan view illustrating an example of a semiconductor manufacturing apparatus according to another exemplary embodiment.

FIG. 5 is a schematic perspective view illustrating the semiconductor manufacturing apparatus according to the exemplary embodiment of FIG. 4.

FIG. 6 is a schematic side view illustrating the semiconductor manufacturing apparatus according to the exemplary embodiment of FIG. 4.

FIGS. 7A and 7B are schematic configuration views illustrating an example of a coating unit in which a film forming process in the semiconductor device manufacturing method illustrated in FIG. 1 may be carried out.

FIG. 8 is a schematic view illustrating a relationship between temperatures of a heating process and LERs in Example 1.

FIGS. 9A to 9F are examples of SEM images of wafers in Example 1.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

In the technologies disclosed in Japanese Patent Laid-Open Publication No. 2012-27144 and Japanese Patent Laid-Open Publication No. 2004-235468, characteristics required for a resist pattern are insufficient.

To solve the foregoing problems, the present invention provides a semiconductor device manufacturing method that manufactures a semiconductor device having a resist pattern which is excellent in roughness property and line width property.

According to the present disclosure, there is provided a semiconductor device manufacturing method. The method includes: forming a film that is elastic and incompatible with a resist to cover a surface of the resist patterned on an object to be processed, and heating the object to be processed that is formed with the film.

In the heating of the object to be processed, a heating temperature may be equal to or higher than a glass transition point of the resist.

The method further includes cooling the object to be processed after the heating of the object to be processed.

The film may be an organic silicon compound film.

The organic silicon compound film may be made of at least one material selected from a group consisting of a silicon alkoxide compound, a silicon chelate compound, a silicon acylate compound, and a silane coupling agent.

The film may be an organic metal compound film.

The organic metal compound film may be made of at least one material selected from a group consisting of a metal alkoxide compound, a metal chelate compound, a metal acylate compound, and an amine-based organic metal compound.

The film is formed to be conformal to the patterned resist.

According to another aspect of the present disclosure, there is provided a semiconductor manufacturing apparatus. The apparatus includes: a resist pattern forming module which includes a resist liquid coating unit, an exposure unit and a developing unit; a film forming module; and a heating module. The resist pattern forming module forms a resist pattern on an object to be processed, the film forming module forms a film that is elastic and incompatible with the resist pattern to cover the resist pattern, and the heating module heats the object to be processed that is formed with the film.

The apparatus may further include a film removing module which removes the film.

According to the present disclosure, there is provided a semiconductor device manufacturing method that manufactures a semiconductor device having a resist pattern which is excellent in roughness property and line width property.

Hereinafter, exemplary embodiments of the present disclosure will be described in detail with reference to drawings.

(Method of Manufacturing Semiconductor Device)

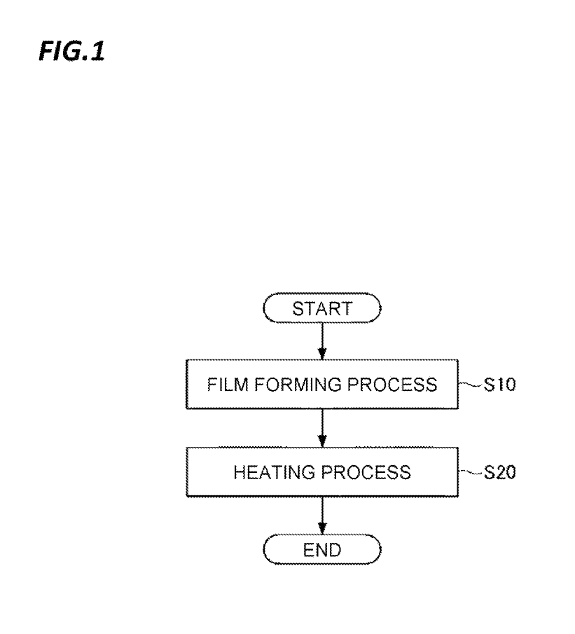

First, a method of manufacturing a semiconductor device according to the exemplary embodiment will be described. FIG. 1 is a flow chart illustrating an example of a semiconductor device manufacturing method according to an exemplary embodiment.

As illustrated in FIG. 1, the semiconductor device manufacturing method according to the exemplary embodiment includes the following processes.

S10: a film forming process for forming a film which is elastic and incompatible with a resist patterned on an object to be processed to cover the surface of the resist,

S20: a heating process for heating the object to be processed formed with the film

The semiconductor device manufacturing method according to the exemplary embodiment may include other processes. Other processes may include, for example, a cooling process for cooling the heated object to be processed, or a film removing process for removing the film from the heated object to be processed.

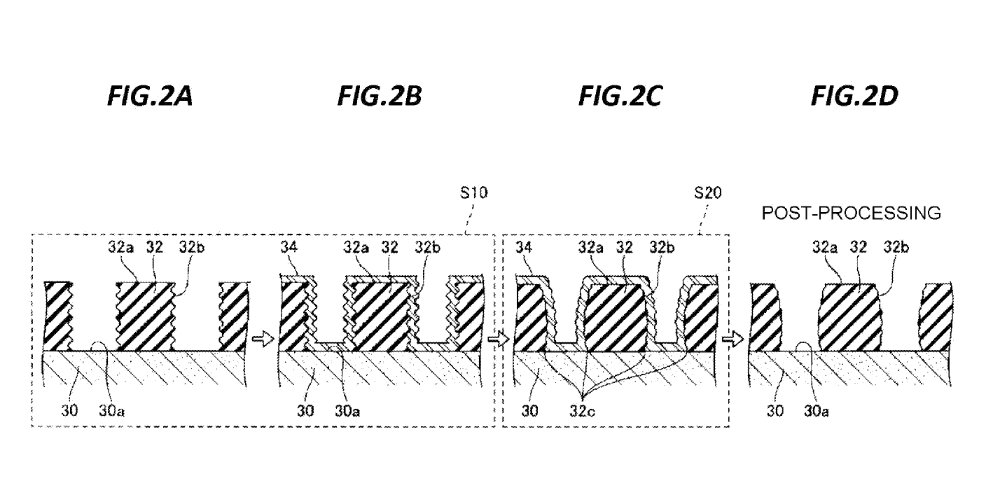

The respective processes will be described in detail with reference to FIG. 2A to 2D. In the description of the exemplary embodiments, the resist pattern to be formed is a line pattern. However, the same technology may be employed in a hole pattern, and the present disclosure is not limited in this regard.

FIGS. 2A to 2D are schematic views for describing a flow of the semiconductor device manufacturing method according to the exemplary embodiment of FIG. 1.

[Film Forming Process S10]

As described above, in the film forming process, a film 34 which is elastic and incompatible with a resist 32 (also referred to as a “resist pattern 32”) is formed to cover the surface of the resist 32 previously patterned on an object to be processed 30 (see FIGS. 2A and 2B).

In the exemplary embodiment, “to cover the surface of the resist 32” indicates that the film 34 covers a top surface 32a and a side surface 32b of the resist 32. Here, a space between the adjacent resist patterns 32 may be entirely or partially filled with the film 34. When the surface of the resist 32 is covered with the film 34, the film 34 may be formed to only partially cover an exposed portion 30a which is not formed with the resist 32, at the surface side of the object to be processed 30 which is formed with the resist 32. However, it is desirable that the film 34 is formed to completely cover the exposed portion 30a. The reason why it is desirable that the film 34 is formed to completely cover the exposed portion 30a will be described in heating process S20 to be described later.

There is no specific limitation in the object to be processed 30. For example, a substrate, or a substrate formed with at least one kind of base layer thereon may be used.

There is no specific limitation in the material for the base layer. For example, an organic-based bottom anti-reflective coating (BARC) film (e.g., an Si-containing film), a tetraethoxysilane (TEOS) film, a spin on glass (SOG) film, an SiON film or a low temperature oxide (LTO) film may be used.

An example of a method of forming the resist pattern 32 on the object to be processed 30, as illustrated in FIG. 2A, will be simply described. First, on the object to be processed 30, the resist 32 is coated by a spin-on method using, for example, a coating/developing device with an exposure device incorporated therein. Before the resist 32 is coated on the object to be processed 30, the object to be processed 30 may be subjected to a hydrophobic treatment (HMDS treatment) to improve the adhesion between the resist 32 and the object to be processed 30. The object to be processed 30 coated with the resist 32 is subjected to a pre-baking processing in order to remove a solvent within the resist 32 so as to uniformly disperse resist molecules. Then, by a photolithography technology, the resist 32 is subjected to an exposure processing in a predetermined pattern. Before the exposure processing, excess resist may be removed by a peripheral exposure processing. After being subjected to the exposure processing, the object to be processed 30 is subjected to a post exposure baking (PEB) processing to diffuse the photosensitive area, and then a developing process is performed. The developed object to be processed 30 is subjected to a post baking processing in order to improve the adhesion of the resist 32, and then formed with the resist pattern 32. As described above, in the exemplary embodiment, the resist pattern 32 may be a hole pattern or a line pattern. The film thickness of the resist 32 or the pitch of the patterned resist 32 is not particularly limited, but may be appropriately selected by a person ordinarily skilled in the art.

In the film forming process of the exemplary embodiment, as illustrated in FIG. 2B, the film 34 which is elastic and incompatible with the resist 32 is formed on the object to be processed 30 formed with the resist pattern 32 to cover the surface of the resist 32.

There is no specific limitation in the film 34 as long as the film 34 is elastic and incompatible with the resist 32. For example, an organic silicon compound film, an organic metal compound film, an amine-based organic metal compound film or a mixed film thereof may be used.

There is no specific limitation in the method of forming the film 34 as long as, the film 34 that is elastic and incompatible with the resist 32 may be formed in the method. For example, when a precursor in a liquid phase is used for the film 34, a spin coating method may be used as the film forming method. When a precursor in a gas phase is used for the film 34, a gas evaporation method may be used as the film forming method. The film formation by the gas evaporation method may be performed at normal pressure or under vacuum. These methods are preferable in that the film 34 may be formed with a good step coverage irrespective of the height or pitch of the resist 32.

It is desirable that the film 34 is formed to be conformal to the pattern of the resist 32. When the film 34 is formed to be conformal to the pattern of the resist 32, the shape of the film 34 may be more easily transformed by conforming to the transformation of the resist 32 in heating process S20 to be described later, as compared to a case where the space between the adjacent resist pattern 32 is filled with the film 34, thereby improving the LER and the LWR more effectively.

When the film 34 is formed by using the spin coating method, a precursor solution which is the above-described material of the film 34 may be coated on the object to be processed 30 formed with the resist pattern 32, and then the film 34 may be formed by, for example, a sol-gel method. In this case, the precursor solution for forming the organic silicon compound film may be, for example, a precursor solution containing a silicon alkoxide compound, a silicon chelate compound, a silicon acylate compound and/or a silane coupling agent. The precursor solution for forming the organic metal compound film may be, for example, a precursor solution containing a metal alkoxide compound, a metal chelate compound and/or a metal acylate compound. The metal compound included in the precursor solution is preferably a metal compound containing titanium, zirconium, tungsten, aluminum, tantalum or hafnium as a main component.

When the gas evaporation method is used under vacuum, for example, an amine-based organic metal compound may be used.

[Heating Process S20]

In the heating process, as illustrated in FIG. 2C, the object to be processed 30 formed with the film 34 is heated.

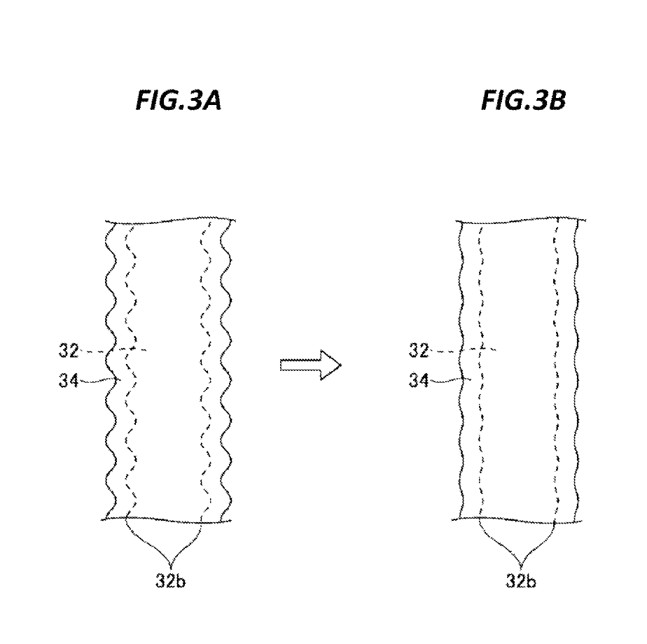

FIGS. 3A and 3B are schematic views illustrating a heating process in the semiconductor device manufacturing method according to the exemplary embodiment of FIG. 1. More specifically, FIG. 3A is an example of a plan view of the resist 32 (immediately) after the film forming process, and FIG. 3B is an example of a plan view of the resist 32 after the heating process.

As illustrated in FIG. 3A, the surface of the side surface 32b of the resist 32 immediately after the film forming process has unevenness. It is believed that this is caused by the wave-like property of light irradiated on the object to be processed 30 during the exposure processing at the time of forming the resist pattern 32.

In the exemplary embodiment, when the resist 32 is heated, the molecular thermal motion is intensified in the resist 32, thereby causing the resist 32 to be thermally expanded and lowering the rigidity and viscosity of the resist 32. Thus, the liquidity of the resist 32 is increased. The resist 32 with the increased liquidity tends to be transformed into a shape with a smaller surface area and a more stable energy state, and thus the side surface 32b of the resist 32 is planarized. Here, since a contact portion 32c of the film 34, the object to be processed 30 and the resist 32 is fixed, the resist pattern 32 does not cause tailing even if the liquidity of the resist 32 is increased. As a result, the resist 32 may be smoothed while a pitch between the adjacent resists 32 is maintained. That is, it may be said that the semiconductor device manufacturing method according to the exemplary embodiment is a process in which the line width of the resist pattern 32 is varied little before and after the processing. In order to further firmly fix the contact portion 32c, it is desirable to form the film 34 to completely cover exposed portions 30a of the object to be processed 30.

The film 34 is elastic, and thus is also planarized to conform to the planarization of the resist 32. As a result, the resist 32 is transformed from the state of FIG. 3B to the state of FIG. 3C such that the roughness of the side surface 32b is smoothed. Accordingly, a resist pattern with a small LER LWR or CER may be formed.

There is no limitation in the temperature at which the resist 32 is heated as long as the temperature is lower than a temperature at which the resist 32 is carbonized. Preferably, the temperature is equal to or higher than a glass transition point of the resist 32. For example, when the glass transition point of the resist 32 is 150° C., the heating temperature preferably ranges from about 150° C. to about 300° C. This is because, when the object to be processed 30 is heated to a temperature which is equal to or higher than the glass transition point of the resist 32, the liquidity of the resist 32 is further increased, thereby further increasing the above-described smoothing effect.

[Other Processes]

The semiconductor device manufacturing method according to the exemplary embodiment may include other processes besides the above-described processes. Other processes may include, for example, a cooling process for cooling the heated object to be processed and a film removing process for removing the film from the heated object to be processed.

Regardless of the semiconductor device manufacturing method according to the exemplary embodiment as described above, a heated object to be processed 30 is usually conveyed to a following process after cooled in the process of manufacturing a semiconductor device. In this case, the object to be processed 30 may be naturally cooled, but preferably is cooled by using a cooling module. Particularly, in a case where a chemical amplification type resist is used as the resist 32, a problem may occur in that the developed line width is expanded when the cooling processing is not rapidly performed after heating processing. As the cooling module, for example, a conventionally known hot/cooling plate (CHP) unit which is used for, for example, resist formation may be used.

The semiconductor device manufacturing method according to the exemplary embodiment may include a film removing process. The object to be processed 30 formed with the resist 32 in the process of manufacturing a semiconductor device is subjected to dry etching using the resist pattern 32 as a mask. When the film 34 is conformally formed in the film forming process, as illustrated in FIG. 2D, the film 34 may be removed by the dry etching, and then the resist 32 exposed by removing the film 34 may be used as a mask to etch the base film (the object to be processed 30) that is exposed in the same manner.

The film 34 may be removed by a wet removal processing using a chemical, instead of dry etching. As a cleaning liquid for removing the film 34, water, an acidic aqueous solution such as, for example, hydrofluoric acid, or an organic solvent such as, for example, alcohol may be used.

(Semiconductor Manufacturing Apparatus)

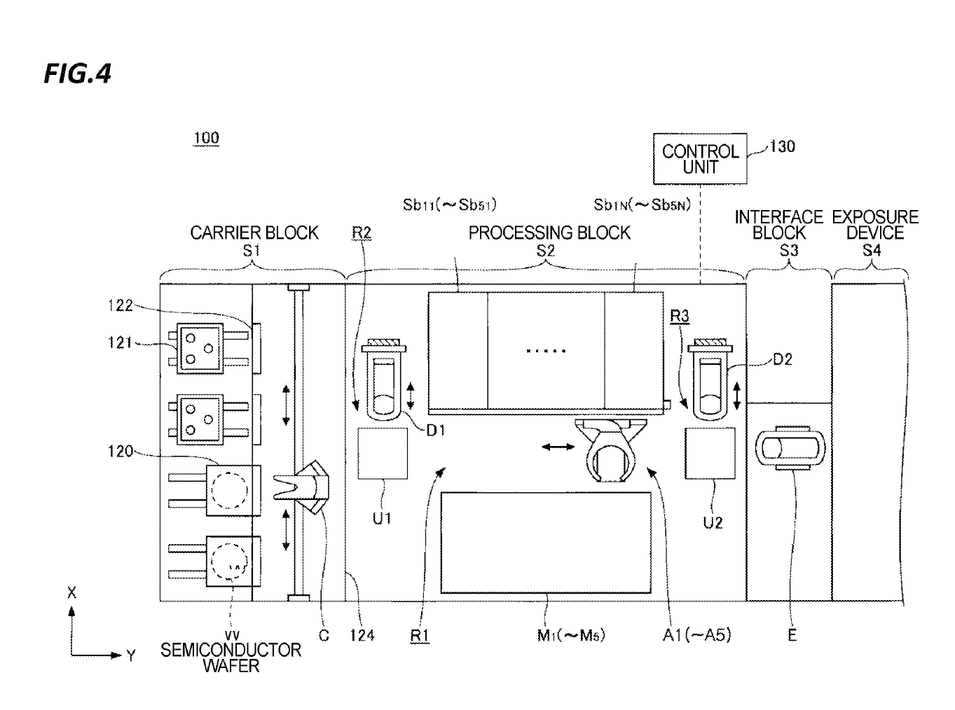

Hereinafter, a semiconductor manufacturing apparatus which may perform the semiconductor device manufacturing method according to the exemplary embodiment as described above will be described with reference to FIGS. 4 to 6. Here, in the following description, a semiconductor manufacturing apparatus which has a resist pattern forming module configured to perform processings consistently from resist liquid coating to development, a film forming module configured to form a film on an object to be processed, and a heating module configured to perform heating processing on a resist will be described as an example.

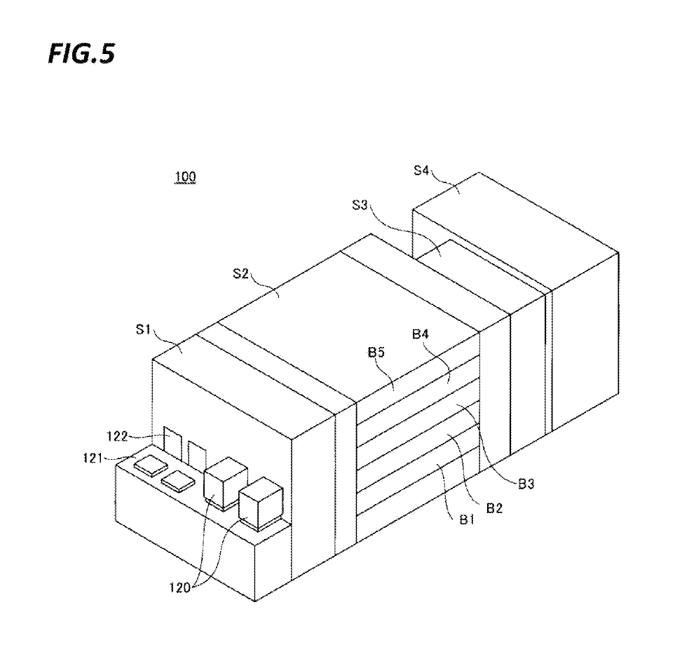

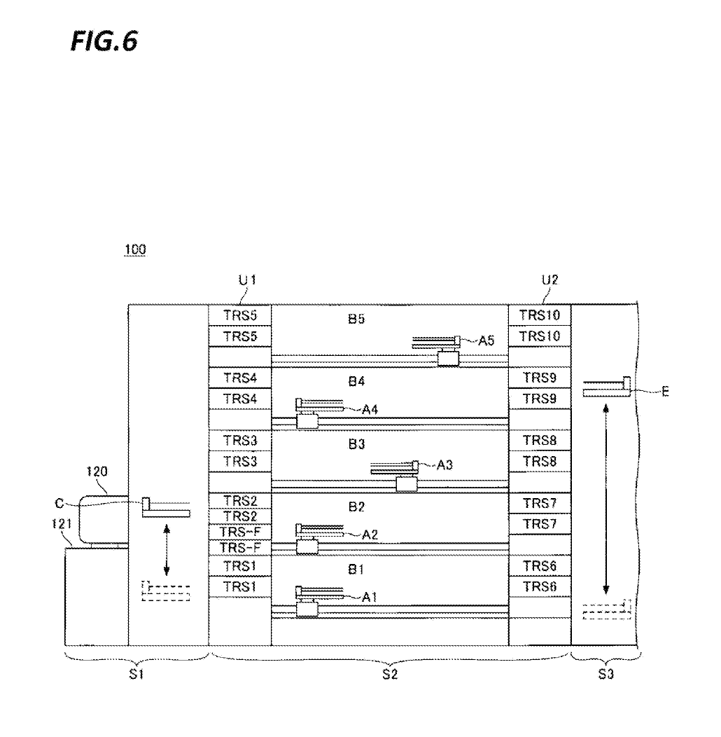

FIG. 4 is a schematic plan view illustrating an example of a semiconductor manufacturing apparatus according to another exemplary embodiment, FIG. 5 is a schematic perspective view illustrating the semiconductor manufacturing apparatus according to the exemplary embodiment of FIG. 4, and FIG. 6 is a schematic side view illustrating the semiconductor manufacturing apparatus according to the exemplary embodiment of FIG. 4. Hereinafter, the X-axis direction of FIG. 4 is considered as a left-right direction of the apparatus, and the Y-axis direction is considered as a front-rear direction of the apparatus. In the X-axis direction, the upper side of FIG. 4 is considered as the left side, and the lower side is considered as the right side, and in the Y-axis direction, the S1 side to be described later of the apparatus is considered as the front side, and the S4 side to be described later is considered as the rear side.

A semiconductor manufacturing apparatus 100 of the exemplary embodiment is provided with a carrier block S1, a processing block S2, an interface block S3, and an exposure device S4.

The carrier block S1 is an area into/from which a carrier 120 is carried. The carrier 120 airtightly accommodates one or more wafers W which are an example of objects to be processed. The carrier block S1 is provided with a mounting stage 121 on which a plurality of carriers 120 may be placed, an opening/closing unit 122 formed on a wall at the rear side (in the Y direction in FIG. 4) of the mounting stage 121, and a transfer arm C.

The transfer arm C may carry the wafers W into/out of the carrier 120 via the opening/closing unit 122, and is configured to be capable of moving forward and backward, moving up and down, and rotating around the vertical axis.

The processing block S2 surrounded by a case 124 is connected to the rear side of the carrier block S1.

In the processing block S2, a plurality of unit blocks are configured to be arranged in the vertical direction. In the exemplary embodiment exemplified in FIG. 5, from the bottom side, a first unit block B1 configured to coat a resist liquid, a second unit block B2 configured to develop a resist film, a third unit block B3 configured to perform the above-described film forming processing of the exemplary embodiment, a fourth unit block B4 configured to heat a wafer formed with the film, and a fifth unit block B5 configured to remove the film are assigned. However, the semiconductor manufacturing device of the exemplary embodiment is not limited to the above described configuration. For example, the fourth unit block B4 configured to heat the wafer formed with the film may be provided as a sub-module of the third unit block B3 to be described later. Other unit blocks may be additionally assigned. For example, another unit block configured to form a base film such as, for example, an anti-reflective film, on the wafers W may be assigned. The above-described unit blocks B1 to B5 may be arranged in a different order.

At the substantially central portion of the processing block S2, a conveyance region R1 of the wafers W is formed. The conveyance region R1 is configured to connect the carrier block S1 to the interface block S3, and extends in the front-rear direction of the processing block S2.

For example, at the right side of the conveyance region R1, main modules M₁ to M₅ configured to perform main processings, which correspond to the unit blocks B1 to B5, respectively, are disposed. At the left side of the conveyance region R1, one or more sub-modules Sb₁₁ to Sb_{5N} (N is an integer of 1 or more), which are configured to perform sub-processings such as, for example, heating or cooling before and after the main processings performed by each main module, are disposed. The sub-modules Sbₓ₁ to Sb_{xN} corresponding to the main modules (Mₓ) may be disposed in the vertical direction in a shelf-like form of multiple stages, or disposed in series in the front-rear direction of the processing block S2.

Specific examples of the sub-modules Sb₁₁ to Sb_{5N} include an alignment unit ALIM configured to perform positioning of the wafers W, an extension unit EXT configured to perform carrying in/out of the wafers W, a hot plate unit HP configured to perform a heating processing such as, for example, pre-baking on a wafer W coated with a resist liquid, a cooling plate unit COL configured to perform a cooling processing, a hot/cooling plate unit CHP configured to perform a heating/cooling processing on the wafers W, a hydrophobic treatment unit AD configured to perform a hydrophobic treatment to improve adhesion between a resist liquid and the wafers W, and a peripheral exposure device configured to selectively expose only an edge portion of a wafer W. As for each sub-module, a conventionally known unit may be used. Thus, in this specification, specific descriptions of the structure of the sub-module will be omitted.

Main arms A1 to A5 are disposed in the conveyance region R1. Each main arm is configured to deliver a wafer W between all modules within each of the unit blocks B1 to B5. Each of the main arms A1 to A5 is configured to be capable of moving forward and backward, moving up and down, and rotating around the vertical axis.

In the conveyance region R1, an area adjacent to the carrier block S1 is set as a first wafer delivery region R2. In the region R2, as illustrated in FIG. 4, a shelf unit U1 is provided at a position to which the transfer arm C and each of the main arms A1 to A5 are accessible, and a delivery arm D1 configured to deliver the wafer W to/from the shelf unit U1 is provided.

The shelf unit U1, as illustrated in FIG. 6, is provided with delivery stages TRS1 to TRS5 which are configured such that the wafers W are delivered to/from the main arms A1 to A5 of the unit blocks B1 to B5, respectively. In the example illustrated in FIG. 6, for each of the unit blocks B1 to B5, one or more delivery stages (e.g., two delivery stages) are provided, and a delivery stage group in which the delivery stages are stacked in multiple stages is formed.

The delivery arm D1 is configured to be capable of moving forward and backward, moving up and down so as to deliver the wafer W to/from the delivery stages TRS1 to TRS5.

As illustrated in FIG. 6, the shelf unit U1 may be provided with two delivery stages TRS-F which are configured such that wafers W are carried into/out of the processing block S2 by the transfer arm C. However, the shelf unit U1 may be configured such that the wafers W may be carried into the processing block S2 via the delivery stages TRS1 to TRS5 without being provided with the delivery stages TRS-F.

In the conveyance region R1, an area adjacent to the interface block S3 is set as a second wafer delivery region R3. In the region R3, as illustrated in FIG. 4, a shelf unit U2 is provided at a position to which each of the main arms A1 to A5 is accessible, and a delivery arm D2 configured to deliver the wafer W to/from the shelf unit U2 is provided.

The shelf unit U2, as illustrated in FIG. 6, is provided with delivery stages TRS6 to TRS10 which are configured such that wafers W are delivered to/from the main arms A1 to A5 of the unit blocks B1 to B5, respectively. In the example illustrated in FIG. 6, each of the unit blocks B1 to B5 is provided with one or more delivery stages (e.g., two delivery stages) and is formed with a delivery stage group in which the delivery stages are stacked in multiple stages.

The delivery arm D2 is configured to be capable of moving forward and backward and moving up and down so as to deliver wafers W to/from the delivery stages TRS6 to TRS10.

At the rear side of the shelf unit U2 in the processing block S2, the interface block S3 is provided, and at the rear side of the interface block S3, the exposure device S4 is provided. In the interface block S3, an interface arm E configured to deliver wafers W to the shelf unit U2 of the processing block S2 and the exposure device S4 is disposed.

The interface arm E serves as a wafer conveyance unit between the processing block S2 and the exposure device S4, and delivers wafers W to/from the delivery stages TRS6 to TRS10 of the respective unit blocks B1 to B5. Accordingly, the interface arm E is configured to be capable of moving forward and backward, moving up and down, and rotating around the vertical axis.

The semiconductor manufacturing apparatus 100 of the exemplary embodiment may freely deliver wafers W by the delivery arm D1 and the delivery arm D2 through the delivery stages TRS1 to TRS5, and the delivery stages TRS6 to TRS10, respectively, among the unit blocks B1 to B5 stacked in five stages.

The semiconductor manufacturing apparatus 100 of the exemplary embodiment is provided with a control unit 130 including a computer configured to perform recipe management of each processing unit, recipe management of a conveyance route of wafers W, each processing in the main modules M₁ to M₅ and the sub-modules Sb₁₁ to Sb_{5N}, and driving control of the main arms A1 to A5, the transfer arm C, the first and second delivery arms D1 and D2, and the interface arm E. In the control unit 130, wafers W conveyed and processed by using the unit blocks B1 to B5.

Hereinafter, descriptions will be made on the configuration of a coating unit within the film forming module configured to perform the film forming process of the exemplary embodiment in the above-described semiconductor manufacturing apparatus 100 of the exemplary embodiment.

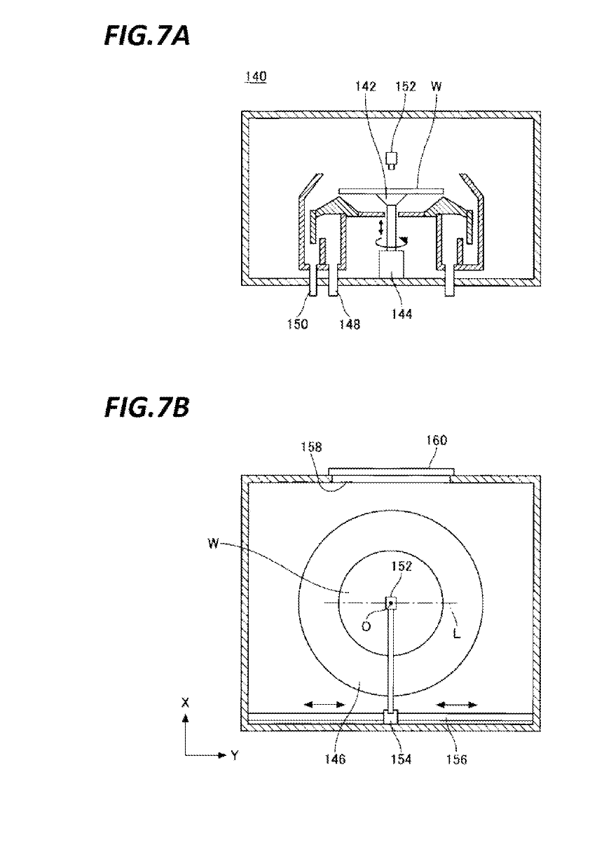

FIGS. 7A and 7B are schematic configuration views illustrating an example of a coating unit in which the film forming process in the semiconductor device manufacturing method illustrated in FIG. 1 may be carried out. A coating unit 140 illustrated in FIGS. 7A and 7B is an example of a coating unit in a case where the film 34 is formed by using a spin coating method employed in Example 1 to be described later. The coating unit may be employed in the main module M₃ of the third unit block B3 which performs a film forming processing in the semiconductor manufacturing apparatus of FIGS. 4 to 6 as described above.

The coating unit 140 includes a substrate holding unit 142. The substrate holding unit 142 is a spin chuck and is configured to horizontally hold the wafer W through vacuum suction. The substrate holding unit 142 is configured to be capable of rotating around the vertical axis, and moving up and down by a driving unit 144. A cup 146 is provided around the substrate holding unit 142 to extend from the wafer W to the substrate holding unit 142, and a drainage unit such as, for example, an exhaust pipe 148 or a drainage pipe 150 is provided below the cup 146.

The coating unit 140 includes a nozzle 152 configured to supply a coating liquid including a precursor of the film 34. The nozzle 152 is provided at the substantially rotational center of the wafer W, and is configured to be capable of moving along a guide member provided in the lengthwise direction of the coating unit 140, and moving up and down, by a moving mechanism 154.

The coating unit 140 includes a wafer carrying-in/out port 158 which is formed through the wall facing the conveyance region of the main arm A3, and an opening/closing shutter 160 is provided in the carrying-in/out port 158.

In the semiconductor device manufacturing method of the exemplary embodiment, a wafer W which has been formed with a predetermined resist pattern in advance is firstly delivered to the substrate holding unit 142 by the main arm A3 through the carrying-in/out port 158. Then, the substrate holding unit 142 is rotated by the driving unit 144 and a coating liquid is supplied from the nozzle 152 to the substantially rotational center of the wafer W. The supplied coating liquid is diffused in the radial direction of the wafer W by the centrifugal force. The coating liquid is supplied to cover the surface of the resist pattern.

The wafer W coated with the coating liquid is subjected to a shaking-off processing and a drying processing of the coating liquid, and then is carried out from the coating unit 140 to a predetermined sub-module (e.g., a hot/cooling plate unit) by the main arm A3 through the carrying-in/out port 158. Then, for example, a baking processing is performed and formation of the film 34 is completed.

The wafer W formed with the film 34 is heated preferably at a temperature equal to or higher than a glass transition point of the resist by a heating module such as, for example, a hot/cooling plate unit, and the method of manufacturing the semiconductor device of the exemplary embodiment is completed.

### Example 1

Descriptions will be made on an example which demonstrates that a resist pattern which is excellent in roughness property and line width property may be obtained by the semiconductor device manufacturing method according to the exemplary embodiment.

An anti-reflective film (BARC) was formed on 8-inch semiconductor wafers as a base film. Then, a resist was coated on the BARC and subjected to exposure and development to obtain a predetermined resist pattern (line pattern). A resist having a glass transition point of about 150° C. was used. The LER of the obtained resist pattern was 3.80 nm.

Then, the wafers formed with the resist pattern were coated with TSAR-100 (manufactured by Tokyo Ohka Kogyo Co., Ltd.) by using the above-described coating unit 140 at 1000 rpm for 10 sec. The coating liquid was shaken off at 1000 rpm for 10 sec, at 2000 rpm for 10 sec, and then at 3000 rpm for 10 sec so as to dry the coating liquid. The coating liquid was baked to form a film which is elastic and incompatible with the resist.

The wafers formed with the film was subjected to a heating processing under a temperature condition of 100° C., 150° C., 200° C. or 300° C. Then, the heated wafers were cooled and washed with 0.5% hydrofluoric acid aqueous solution for 1 min to remove (release) the film. After removing the film, the LERs of the resists on the wafers were measured.

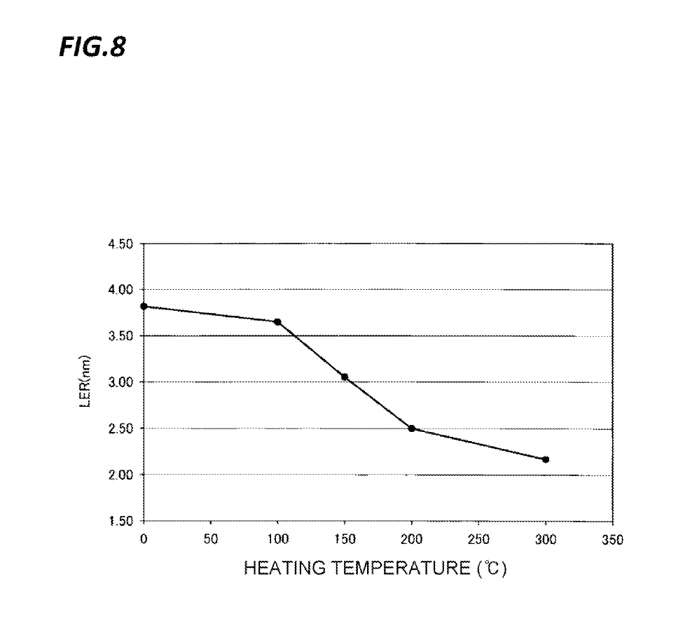

FIG. 8 is a schematic view illustrating the relationship between the temperature of the heating process and the LER in Example 1. In FIG. 8, the horizontal axis represents a heating processing temperature in the heating process, and the vertical axis represents an LER of an obtained resist.

As illustrated in FIG. 8, it was found that, when a film that is elastic and incompatible with a resist is formed and an object to be processed formed with the film is heated, the LER of the obtained resist can be reduced.

The effect of reducing the LER tends to be increased as the heating temperature in the heating process is increased. Especially, in the heating process, in an example where the heating is performed at a temperature equal to or higher than the glass transition point of the resist (at about 150° C. or higher in the present example), the resist has a very small LER value. This is because the liquidity of the resist is increased when the wafer W is heated at a higher temperature, preferably a temperature equal to or higher than the glass transition point of the resist.

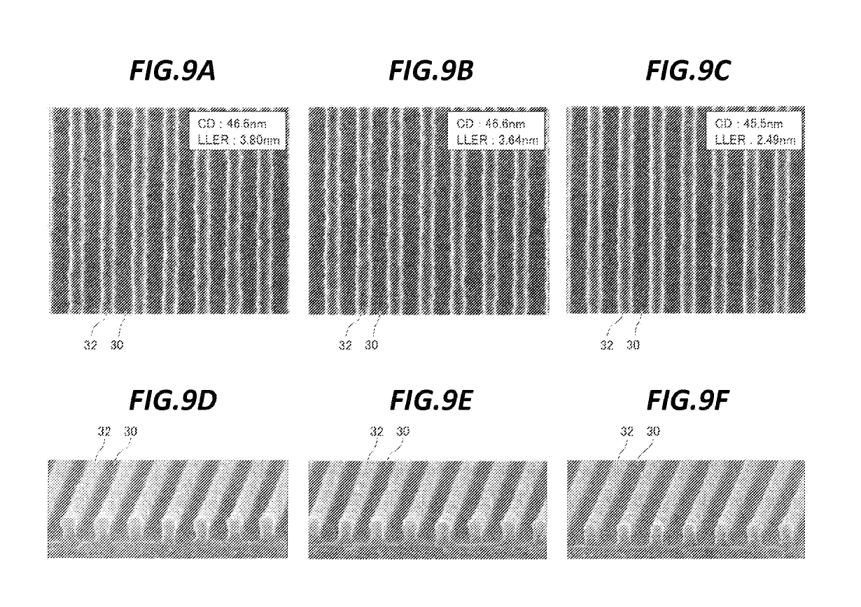

FIGS. 9A to 9F are examples of SEM images of wafers in Example 1. More specifically, FIG. 9A illustrates an SEM image of the top surface of a wafer after forming a resist (LER=3.80 nm), FIG. 9B illustrates an SEM image of the top surface of the wafer after performing the film forming process, the heating process (heating temperature=100° C.) and the film removing process, and FIG. 9C illustrates an SEM image of the top surface of the wafer after performing the film forming process, the heating process (heating temperature=200° C.) and the film removing process. FIG. 9D illustrates a perspective SEM image of the wafer after forming a resist (LER=3.80 nm), FIG. 9E illustrates a perspective SEM image of the wafer after performing the film forming process, the heating process (heating temperature=100° C.), and the film removing process, and FIG. 9F illustrates a perspective SEM image of the wafer after performing the film forming process, the heating process (heating temperature=200° C.) and the film removing process.

FIGS. 9A to 9F illustrate CD values and LER values of the resists in the respective examples. In FIGS. 9A to 9F, “LLER” refers to an LER value of the left side surface of a resist on each SEM image.

As illustrated in FIGS. 9A to 9F, it may be seen that the semiconductor device manufacturing method according to the exemplary embodiment is a process which may reduce LERs and vary CD values little.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A semiconductor device manufacturing method comprising:
forming a film that is elastic and incompatible with a resist to cover a surface of the resist patterned on an object to be processed, and
heating the object to be processed that is formed with the film.

2. The method of claim 1, wherein a heating temperature in the heating of the object to be processed is equal to or higher than a glass transition point of the resist.

3. The method of claim 1, further comprising cooling the object to be processed after the heating of the object to be processed.

4. The method of claim 1, wherein the film is an organic silicon compound film.

5. The method of claim 4, wherein the organic silicon compound film is made of at least one material selected from a group consisting of a silicon alkoxide compound, a silicon chelate compound, a silicon acylate compound, and a silane coupling agent.

6. The method of claim 1, wherein the film is an organic metal compound film.

7. The method of claim 6, wherein the organic metal compound film is made of at least one material selected from a group consisting of a metal alkoxide compound, a metal chelate compound, a metal acylate compound, and an amine-based organic metal compound.

8. The method of claim 1, wherein the film is formed to be conformal to the patterned resist.

9. A semiconductor manufacturing apparatus comprising:
a resist pattern forming module which includes a resist liquid coating unit, an exposure unit and a developing unit, the resist pattern forming module being configured to form a resist pattern on an object to be processed,
a film forming module configured to form a film that is elastic and incompatible with the resist pattern to cover the resist pattern, and
a heating module configured to heat the object to be processed formed with the film.

10. The semiconductor manufacturing apparatus of claim 9, further comprising a film removing module configured to remove the film.
